(19) United States
(12) Patent Application Publication
(10) Pub. No.: US 2026/0087189 A1
(43) Pub. Date: Mar. 26, 2026

(54) AI-Driven Structural Engineering Design System and Method

(71) Applicant: Alexander Davis, Oxnard, CA (US)

(72) Inventor: Alexander Davis, Oxnard, CA (US)

(21) Appl. No.: 18/890,835

(22) Filed: Sep. 20, 2024

(51) Int. Cl. G06F 30/13; G06F 30/27; G06N 20/00

(52) U.S. Cl. CPC G06F 30/13; G06F 30/27; G06N 20/00

(57) ABSTRACT

A data processing system and method for generating structural engineering documents using artificial intelligence (AI) is disclosed. The system comprises a memory storing a dataset of engineered structures, including instances of structural failures, and a machine learning model trained on the dataset to perform structural analysis and generate optimized design documents. The AI system receives input data specifying design requirements, simulates the structure's behaviours under various conditions, and generates structural engineering documents, including 3D CAD models, based on an optimal combination of materials. The system may include a feedback integration module for continuous refinement of the machine learning model, an analytics engine for performance monitoring, and an electronic filing integration for streamlining the design approval process. The AI system learns from past projects to rapidly generate code-compliant, cost-optimized, and resilient structural designs.

### BACKGROUND OF THE INVENTION

### Field of Invention

The present disclosure relates to the field of artificial intelligence systems for generating structural engineering documents and designs.

### Description of Related Art

Structural engineering involves designing the frameworks and skeletons that support and stabilize various structures such as buildings, bridges, tunnels, and dams. Structural engineers must ensure these structures are safe, strong, stable, durable and economical by carefully analyzing and selecting optimal combinations of materials, shapes, and reinforcements to adequately resist stresses and loads.

Conventionally, structural analysis and design has been a time-consuming manual process requiring deep expertise in engineering mechanics, material science, and building codes and standards. Engineers must determine, often via hand calculations, how prospective designs will behave under myriad stresses like compression, tension, shear, bending, and torsion, as well as environmental conditions including temperature extremes, corrosion, blast forces and radiation. Developing and comparing multiple design options to optimize cost, constructability and resilience is challenging and laborious.

While computer-aided design (CAD) software has assisted with drafting and modeling, the structural engineering process itself has lacked sophisticated automation tools. Existing software is limited to digitizing traditional workflows rather than autonomously generating or optimizing designs. The underlying structural analysis and code compliance checks still require manual review and calculation.

Accordingly, there is a need in the field of structural engineering for an artificial intelligence system capable of automatically generating code-compliant structural designs and documentation by learning engineering principles from prior projects. Such a system could streamline structural design workflows, reduce the risk of errors and omissions, optimize design performance and efficiency, and ultimately produce safer and more economical structures.

### BRIEF SUMMARY OF THE INVENTION

This summary is provided to introduce a selection of concepts, in a simplified format, that are further described in the detailed description of the invention. This summary is neither intended to identify key or essential inventive concepts of the invention nor is it intended for determining the scope of the invention.

The present invention provides a data processing system and method for generating structural engineering documents using artificial intelligence (AI). A memory stores a dataset of engineered structures, including instances of structural failures. A machine learning model is trained on this dataset to enable the AI to perform sophisticated structural analysis and generate optimized design documents.

In various embodiments, the AI system receives input data specifying design requirements for a target structure. The trained machine learning model then simulates the structure's behaviors under various stresses, loads, and environmental conditions. Based on this analysis, the AI selects an optimal combination of materials and generates the structural engineering documents, including 3D computer-aided design (CAD) models.

The system may further include a feedback integration module that allows the AI to learn from user feedback, engineer input, and real-world structural data. This enables continuous refinement of the machine learning model. An analytics engine provides performance monitoring, while an electronic filing integration streamlines the design approval process.

Advantageously, the automated AI system learns from past projects to rapidly generate code-compliant, cost-optimized, and resilient structural designs. By modeling a broad range of loading scenarios and failure modes, the AI can identify non-obvious solutions that a human engineer may overlook. The system can shorten design cycles from months to days, reduce labor costs, improve structure safety and durability, and ultimately make high-quality structural engineering more accessible.

In one embodiment, the AI system's structural analysis includes finite element analysis (FEA) to model structures using NURBS surfaces. In another embodiment, the AI can propose novel combinations of conventional and innovative materials like high-performance concretes and polymers to simultaneously optimize strength and constructability.

The AI-generated designs may integrate IoT sensors to provide real-time structural health monitoring data, which can feed back into the machine learning model. In the event of a structural failure, the AI can analyze the data to identify the cause and update its design algorithms to prevent recurrence.

This powerful AI platform has the potential to disrupt the structural engineering field and redefine the built environment. Its ability to learn from experience, model complex behaviors, and optimize designs across multiple objectives could enable groundbreaking improvements in structure safety, performance, sustainability, and affordability. The present invention represents an important leap forward for AI in engineering design.

Additional features and advantages of the invention will be set forth in the description which follows. These and other features of the present invention will become more fully apparent from the following description, or may be learned by the practice of the invention as set forth hereinafter.

### BRIEF DESCRIPTION OF THE DRAWINGS

The various exemplary embodiments of the present invention, which will become more apparent as the description proceeds, are described in the following detailed description in conjunction with the accompanying drawings, in which:

FIG. 1 is a block diagram illustrating, by way of example and not limitation, the primary components of a data processing system that may be used for generating structural engineering documents according to an embodiment of the invention.

FIG. 2 illustrates a user interface for interacting with the data processing system described in FIG. 1, according to an embodiment of the invention.

FIG. 3 illustrates a method for generating structural engineering documents using the data processing system and user interface, according to an embodiment of the present invention.

FIG. 4 is a detailed flow diagram illustrating, by way of example and not limitation, the process of training the machine learning model, according to an embodiment of the invention.

### DETAILED DESCRIPTION

In the following detailed description of the preferred embodiments, reference is made to the accompanying drawings, which form a part hereof and show, by way of illustration, specific embodiments in which the invention may be practiced. It is to be understood that other embodiments may be used and structural or logical changes may be made without departing from the scope of the present invention. The following detailed description, therefore, is not to be taken in a limiting sense, and the scope of the present invention is defined by the appended claims.

The following description is provided as an enabling teaching of the present systems, and/or methods in its best, currently known aspect. To this end, those skilled in the relevant art will recognize and appreciate that many changes can be made to the various aspects of the present systems described herein, while still obtaining the beneficial results of the present disclosure. It will also be apparent that some of the desired benefits of the present disclosure can be obtained by selecting some of the features of the present disclosure without utilizing other features.

Accordingly, those who work in the art will recognize that many modifications and adaptations to the present disclosure are possible and can even be desirable in certain circumstances and are a part of the present disclosure. Thus, the following description is provided as illustrative of the principles of the present disclosure and not in limitation thereof.

The terms “a” and “an” and “the” and similar references used in the context of describing a particular embodiment of the present invention (especially in the context of certain claims) are construed to cover both the singular and the plural. The recitation of ranges of values herein is merely intended to serve as a shorthand method of referring individually to each separate value falling within the range. Unless otherwise indicated herein, each individual value is incorporated into the specification as if it were individually recited herein.

All systems described herein can be performed in any suitable order unless otherwise indicated herein or otherwise clearly contradicted by context. The use of any and all examples, or exemplary language (for example, “such as”) provided with respect to certain embodiments herein is intended merely to better illuminate the application and does not pose a limitation on the scope of the application otherwise claimed. No language in the specification should be construed as indicating any non-claimed element essential to the practice of the application. Thus, for example, reference to “an element” can include two or more such elements unless the context indicates otherwise.

As used herein, the terms “optional” or “optionally” mean that the subsequently described event or circumstance can or cannot occur, and that the description includes instances where said event or circumstance occurs and instances where it does not.

The word or as used herein means any one member of a particular list and also includes any combination of members of that list. Further, one should note that conditional language, such as, among others, “can,” “could,” “might”, or “may” unless specifically stated otherwise, or otherwise understood within the context as used, is generally intended to convey that certain aspects include, while other aspects do not include, certain features, elements and/or steps. Thus, such conditional language is not generally intended to imply that features, elements and/or steps are in any way required for one or more particular aspects or that one or more particular aspects necessarily include logic for deciding, with or without user input or prompting, whether these features, elements and/or steps are included or are to be performed in any particular aspect.

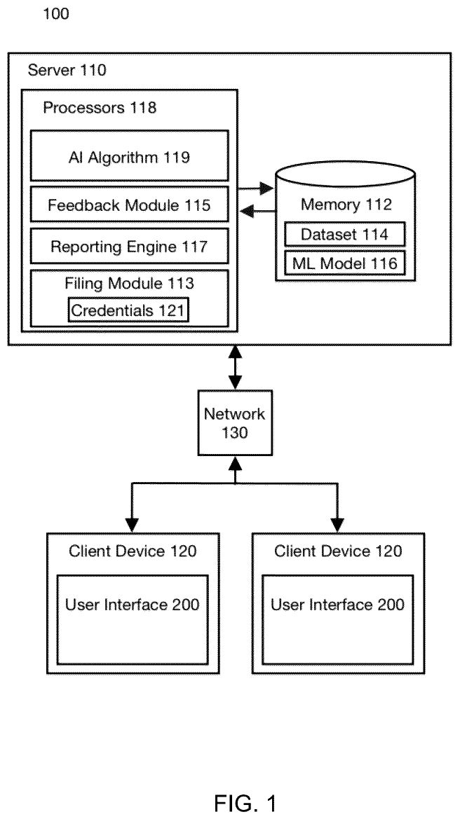

FIG. 1 is a block diagram illustrating, by way of example and not limitation, the primary components of a data processing system (100) that may be used for generating structural engineering documents according to an embodiment of the invention. As shown in FIG. 1, the system (100) generally comprises a server (110) coupled to one or more client devices (120) with one or more user interfaces 200 via a network (130), wherein the network (130) can be a local area network (LAN), wide area network (WAN), the Internet, or any combination thereof.

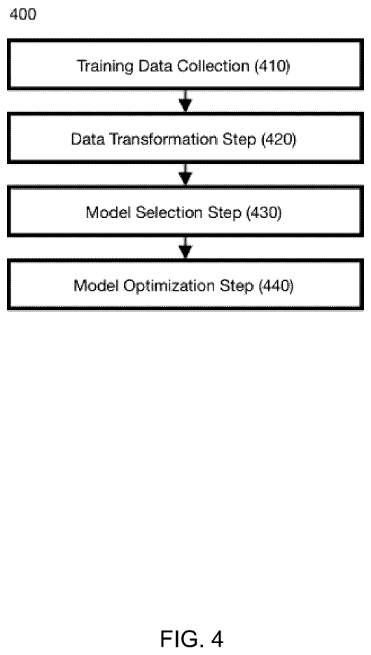

With continued reference to FIG. 1, the server (110) includes a memory (112) configured to store a dataset (114) that may include, but is not limited to, data related to engineered structures and instances of structural failures. In one embodiment, the dataset (114) can optionally include historical data, case studies, building codes, material properties, and other information that may be relevant for training the machine learning model (116) (further depicted in FIG. 4). The memory (112) also stores the machine learning model (116) that has been trained using the dataset (114). In another embodiment, the machine learning model (116) might be based on various algorithms including, but not limited to, artificial neural networks (ANNs), support vector machines (SVMs), decision trees, or ensemble methods.

As further depicted in FIG. 1, the server (110) includes one or more processors (118) configured to execute an artificial intelligence (AI) algorithm (119) that utilizes the trained machine learning model (116). In one embodiment, the processors (118) can be central processing units (CPUs), graphics processing units (GPUs), or any combination thereof, depending on the computational requirements of the AI algorithm (119). The AI algorithm (119) is designed to receive input data for a target structure from the client devices (120) over the network (130), wherein the input data may include, but is not limited to, architectural plans, site conditions, design requirements, and performance criteria for the target structure.

Upon receiving the input data, the AI algorithm (119) performs structural analysis on the target structure by simulating its structural behaviors under various stresses and environmental conditions. In one embodiment, the structural analysis may include determining the structure's response to loads such as, but not limited to, wind, earthquake, snow, ocean waves, and temperature effects. It also typically involves analyzing the structure's performance under stresses including, but not limited to, compression, tension, shear, bending, and twisting, as well as environmental conditions such as ambient temperature, corrosive environments, blast, and radiation.

According to an embodiment, the AI algorithm (119) may employ finite element analysis (FEA) techniques to model these structural behaviors. FEA generally involves discretizing the target structure into smaller elements, applying boundary conditions and loads, and solving the resulting system of equations to determine the structure's response. In one embodiment, the AI algorithm (119) may utilize commercial FEA software packages such as, but not limited to, ANSYS, ABAQUS, or COMSOL, or custom-developed FEA solvers that are substantially optimized for the specific structural analysis tasks.

Based on the structural analysis, the AI algorithm (119) determines an optimal combination of materials for the structural elements of the target structure. In one embodiment, the materials are selected from options including, but not limited to, steel, concrete, timber, aluminum, plastic, and innovative new materials such as carbon fiber reinforced polymers (CFRP), glass fiber reinforced polymers (GFRP), or shape memory alloys (SMAs), wherein the AI algorithm (119) considers factors such as, but not limited to, strength, stiffness, durability, cost, and environmental impact when selecting the materials.

With reference to FIG. 1, the server (110) may also include a feedback integration module (115) that can be configured to receive user feedback and engineer feedback regarding the generated structural engineering documents from the client devices (120), wherein the feedback might include, by way of example and not limitation, suggestions for improvement, identification of inconsistencies or potential errors, or general validation of the structural design. The feedback integration module (115) is further configured to update the dataset (114) based on the received feedback and periodically retrain the machine learning model (116) using the updated dataset, thereby allowing the AI algorithm (119) to learn additional structural engineering requirements, building codes, and best practices over time, substantially improving its accuracy and effectiveness.

As generally depicted in FIG. 1, the data processing system (100) may further comprise an analytics and reporting engine (117) configured to provide analytical data analysis of the AI system's capabilities. In one embodiment, the analytics and reporting engine (117) gathers insights on system performance, usage patterns, and user satisfaction by monitoring key performance indicators (KPIs) including but not limited to processing time, resource utilization, and user feedback scores, and generates dashboards, reports, and visualizations to help system administrators and developers identify areas for improvement and optimize the system's performance.

The analytics and reporting engine (117) can be implemented as a software module running on the server (110), utilizing the server's processing power and memory resources to perform its functions. It is communicatively coupled to the server (110) via internal data buses or other inter-process communication mechanisms, allowing it to access and analyze data from various components of the system (100), such as the AI algorithm (119), the feedback integration module (115), and the electronic filing integration module (113). Moreover, the analytics and reporting engine (117) might also interact with external data sources (not shown), such as third-party analytics platforms or data warehouses, through APIs or data integration pipelines to enhance its analytical capabilities.

Additionally, an electronic filing integration module (113) can be coupled to the server (110), wherein the electronic filing integration module (113) is generally configured to streamline the submission of the generated structural engineering documents to relevant building departments. In one embodiment, the module (113) automatically formats the documents according to the specific requirements of each building department, fills out necessary forms and applications, and submits them electronically, thereby often reducing the time and effort required for manual filing. The electronic filing integration module (113) can be implemented as a software component running on the server (110), leveraging the server's processing power and network connectivity to perform its tasks. It is communicatively connected to the server (110) through internal data buses, APIs, or other inter-process communication mechanisms, enabling it to receive the generated structural engineering documents from the AI algorithm (119) and interact with the building departments'electronic filing systems. Furthermore, the electronic filing integration module (113) may store and manage the necessary credentials (121), such as API keys or digital certificates, to authenticate and securely communicate with the external filing systems.

In operation, the data processing system (100) executes a method for generating structural engineering documents. The method generally comprises training the machine learning model (116) using the dataset (114) of engineered structures and instances of structural failures, receiving input data for a target structure from client devices (120), performing structural analysis on the target structure using the trained machine learning model (116), generating structural engineering documents based on the analysis, and submitting the documents to relevant building departments via the electronic filing integration module (113). Moreover, the method also includes receiving user and engineer feedback, updating the dataset (114), and retraining the machine learning model (116) based on the feedback, as well as providing analytical data analysis and reporting to drive continuous improvement of the system.

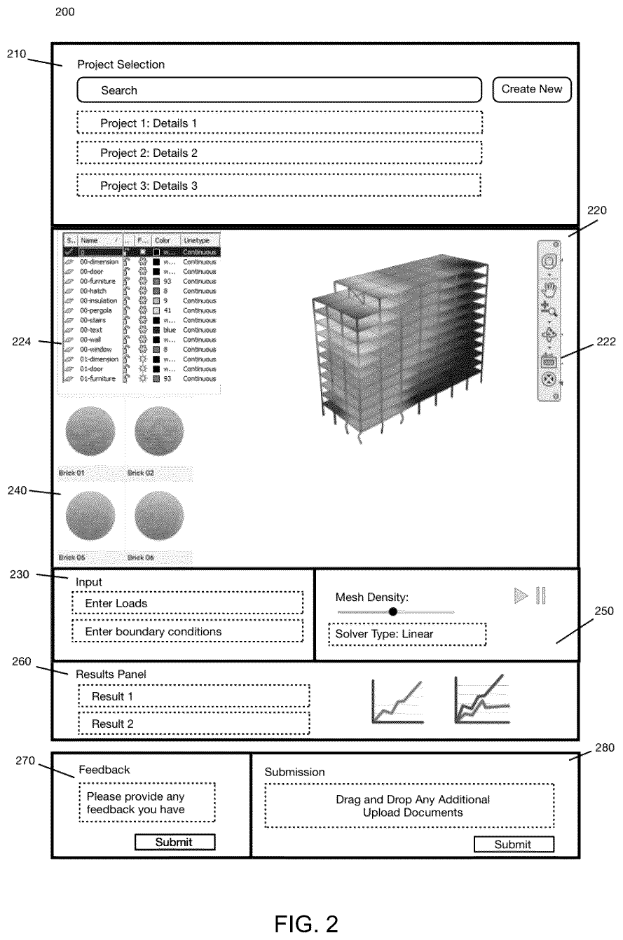

FIG. 2 illustrates a user interface (200) for interacting with the data processing system (100) described in FIG. 1, according to an embodiment of the invention. The user interface (200) comprises a project selection panel (210), wherein said project selection panel (210) is configured to allow users to create new structural engineering projects or access existing projects stored on the server (110). The project selection panel (210) is further configured to communicate with the server (110) via the network (130), thereby retrieving project data and updating project files.

In one embodiment, upon selecting a project, the user is presented with a main design view (220) that is configured to display a 3D rendering of the target structure based on the CAD model generated by the AI algorithm (119). The main design view (220) can utilize Non-Uniform Rational B-Splines (NURBS) surfaces to represent the geometry of the structural elements. Users may interact with the 3D model using navigation controls (222) to manipulate the view, including but not limited to rotating, panning, and zooming the view, as well as toggle the visibility of different structural components using a layer control panel (224).

As depicted in FIG. 2, the user interface (200) also includes an input panel (230) that is configured to specify design requirements, site conditions, and performance criteria for the target structure. The input panel (230) comprises fields for entering data including but not limited to loads, boundary conditions, material properties, and design constraints.

In another embodiment, a materials library (240) is accessible from the user interface (200), allowing users to browse and select from a database of available materials for the structural elements. The materials library (240) can provide detailed information on each material's mechanical properties, cost, environmental impact, and application guidelines. Users may drag and drop materials from the library onto specific structural elements in the main design view (220), thereby assigning them.

The user interface (200) further comprises a simulation control panel (250) that is configured to enable users to initiate and manage the structural analysis process performed by the AI algorithm (119). Users can specify analysis settings, including but not limited to mesh density, solver type, and convergence criteria, and monitor the progress of the analysis through real-time status updates and visualizations.

Alternatively, once the structural analysis is complete, the user interface (200) is configured to display the results in a dedicated results panel (260). The results panel (260) can present key metrics such as stresses, displacements, and factors of safety for each structural element, along with graphical representations of the structure's deformed shape and stress distribution. Users may interact with the results, plotting graphs, and generating reports for further analysis and communication with stakeholders.

In another embodiment, a feedback panel (270) is disposed on the user interface (200), allowing users to optionally provide input and suggestions regarding the generated structural engineering documents. Users can leave comments, mark up the CAD model, and rate the overall quality and effectiveness of the AI-generated design. This feedback can be captured by the feedback integration module (115) on the server (110) and used to update the dataset (114) and retrain the machine learning model (116), thereby enabling continuous improvement.

Finally, the user interface (200) includes a submission panel (280) that is configured to facilitate the electronic filing of the structural engineering documents with the relevant building departments. The submission panel (280) communicates with the electronic filing integration module (113) on the server (110) to automatically format and submit the necessary documents, forms, and applications based on the specific requirements of each building department. Users may track the status of their submissions and receive notifications when additional actions are required.

The present invention can be applied as well for engineering of vehicles, airplanes, ships, and spacecraft. The present invention is not limited to structural engineering but rather can be applied in a variety of contexts, including civil engineering, mechanical engineering, electrical engineering, chemical engineering, systems engineering, environmental engineering, aerospace engineering, nuclear engineering, and nanoscale engineering.

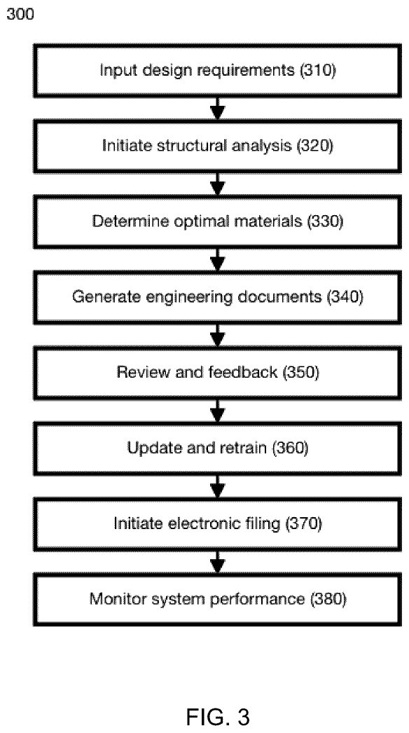

FIG. 3 illustrates a method (300) for generating structural engineering documents using the data processing system (100) and user interface (200) described in FIGS. 1 and 2, by way of example and not limitation, according to an embodiment of the present invention.

In one embodiment, the method (300) begins with a user logging into the system via the user interface (200) and selecting or creating a project using the project selection panel (210). The user then inputs design requirements, site conditions, and performance criteria for the target structure using the input panel (230) (step 310), wherein said input data may comprise loads, boundary conditions, material properties, and design constraints, which are communicated to the server (110) over the network (130). It should be understood that the input data may include, but is not limited to, the aforementioned parameters.

Upon receiving the input data, the server (110) initiates the structural analysis process performed by the AI algorithm (119) (step 320). In another embodiment, the user can control and monitor the analysis using the simulation control panel (250) on the user interface (200), wherein the AI algorithm (119) employs the trained machine learning model (116) and finite element analysis (FEA) techniques to simulate the target structure's behaviors under various stresses and environmental conditions. The AI algorithm (119) may utilize additional computational methods to analyze the structure's performance, as would be apparent to those skilled in the art.

Based on the structural analysis, the AI algorithm (119) determines a substantially optimal combination of materials for the structural elements, selecting from the materials library (240) accessed through the user interface (200) (step 330). In one embodiment, the selected materials are communicated back to the user interface (200) and displayed in the main design view (220). The term “substantially optimal” can used to indicate that the selected combination of materials is close to, but not necessarily, the absolute best solution.

As shown in FIG. 3, the AI algorithm (119) then generates one or more structural engineering documents, including a 3D computer-aided design (CAD) model utilizing Non-Uniform Rational B-Splines (NURBS) surfaces (step 340), wherein the generated documents are transmitted to the user interface (200) and presented in the main design view (220) and results panel (260). The CAD model may employ other mathematical representations of surfaces, such as Bézier surfaces or subdivision surfaces, as would be apparent to those skilled in the art.

In another embodiment, the user reviews the AI-generated structural engineering documents and provides feedback using the feedback panel (270) on the user interface (200) (step 350), wherein the feedback, which may comprise comments, markups, and ratings, is captured by the feedback integration module (115) on the server (110) and used to update the dataset (114) and retrain the machine learning model (116) (step 360). The feedback mechanism allows for continuous improvement of the AI algorithm's performance.

According to an embodiment, if the user is satisfied with the generated documents, they can initiate the electronic filing process using the submission panel (280) on the user interface (200) (step 370), wherein the electronic filing integration module (113) on the server (110) automatically formats and submits the necessary documents, forms, and applications to the relevant building departments based on their specific requirements. The electronic filing process may involve additional steps or variations depending on the jurisdiction and project type.

Further, multiple internal users as well as external users such as independent consultants and special inspectors can be included in processes according to embodiments of the present invention. Small projects may have one engineer (i.e., a Professional Engineer) as engineer of record responsible for officially approving structural plans, while large products may have several PEs plus quality control personnel.

External users can also include regulators such as local governments for buildings, the Federal Aviation Administration for aircraft, and the National Highway Transportation Safety Administration for automobiles. The present invention provides a way of seamlessly handling interactions between government and private parties.

As depicted in FIG. 3, throughout the method (300), the analytics and reporting engine (117) on the server (110) monitors system performance, usage patterns, and user satisfaction (step 380), thereby gathering insights on key performance indicators (KPIs) such as processing time, resource utilization, and user feedback scores, and generates dashboards, reports, and visualizations to help improve the system's performance. The specific KPIs monitored and the format of the generated reports may vary based on the needs of the system administrators and stakeholders.

FIG. 4 illustrates, by way of example and not limitation, the process of training the machine learning model (116) according to an embodiment of the invention (400). As shown in FIG. 4, the training process generally begins with the collection and preparation of the training data (step 410), wherein said training data may be derived from the dataset (114) stored in the memory (112) of the server (110). In one embodiment, the dataset (114) can comprise, but is not limited to: historical data on engineered structures, such as design documents, material specifications, and performance records; case studies of structural failures, which may include investigation reports and root cause analyses; building codes and standards from various jurisdictions; material properties for common and innovative construction materials; and site conditions and environmental factors for different locations.

With reference to FIG. 4, the training data then typically undergoes a data transformation step (step 420) to convert it into a format suitable for training the machine learning model (116). This can involve, by way of example and not limitation: data cleaning using techniques such as deduplication, outlier detection, and imputation of missing values; data normalization using methods such as min-max scaling or z-score standardization; and feature engineering, which optionally includes creating interaction terms, polynomial features, or domain-specific indicators.

As depicted in FIG. 4, the transformed training data is then generally used to train and validate several candidate models in the model selection step (step 430). According to an embodiment, the candidate models may include, but are not limited to: Artificial Neural Networks (ANNs), Support Vector Machines (SVMs), and Decision Trees and Random Forests.

The performance of each candidate model is preferably evaluated using appropriate metrics such as accuracy, precision, recall, F1-score, or mean squared error (MSE), depending on the task. As illustrated in FIG. 4, the best-performing model is then typically selected and further fine-tuned in the model optimization step (step 440). This can involve techniques such as, by way of example and not limitation: hyperparameter tuning using methods like grid search or Bayesian optimization to find a preferred combination of model parameters; regularization techniques such as L1/L2 regularization or dropout to mitigate overfitting; ensemble methods such as bagging or boosting to combine multiple models for improved performance;

In another embodiment, the optimized model is then generally deployed as part of the AI algorithm (119) to generate structural engineering documents. Wherein the model's predictions, such as recommended materials or structural performance metrics, are typically used as inputs to subsequent steps in the AI algorithm, such as the finite element analysis (FEA) and the generation of the final structural engineering documents, thereby enabling the generation of optimized structural designs.

Based on the detailed description provided herein, a skilled artisan would be able to re-create the claimed invention without undue experimentation. The examples above describe the key aspects of the invention in sufficient detail to allow a person having ordinary skill in the field of structural engineering and data processing systems to make and use the invention.

The embodiments described herein are given for the purpose of facilitating the understanding of the present invention and are not intended to limit the interpretation of the present invention. The respective elements and their arrangements, materials, conditions, shapes, sizes, or the like of the embodiment are not limited to the illustrated examples but may be appropriately changed. Further, the constituents described in the embodiment may be partially replaced or combined together.

What is claimed is:

1. A data processing system for generating structural engineering documents, comprising:
a. a memory configured to store a dataset of engineered structures and instances of structural failures;
b. a machine learning model trained using the dataset of engineered structures and instances of structural failures;
c. one or more processors configured to execute an artificial intelligence (AI) algorithm that utilizes the trained machine learning model to:
i. receive input data for a target structure;
ii. perform structural analysis on the target structure by simulating structural behaviors under various stresses and environmental conditions;
iii. generate one or more structural engineering documents for the target structure based on the structural analysis; and
d. a feedback integration module configured to:
i. receive user feedback and engineer feedback regarding the generated structural engineering documents;
ii. update the dataset of engineered structures based on the received feedback; and
iii. retrain the machine learning model using the updated dataset.

2. The data processing system of claim 1, wherein the machine learning model is trained using instances of structural failures, including collapses of structures.

3. The data processing system of claim 1, wherein the structural analysis further includes determining material properties of structural elements, including density, hardness, stiffness, tensile strength, compressive strength, and shear strength.

4. The data processing system of claim 1, wherein the structural analysis includes simulating structural behaviors under various environmental conditions, including ambient temperature, corrosive environments, blast, and radiation.

5. The data processing system of claim 1, wherein generating the structural engineering documents includes selecting an optimal combination of materials from a group comprising steel, concrete, timber, aluminum, plastic.

6. The data processing system of claim 1, further comprising an analytics and reporting engine configured to provide analytical data analysis of the AI system's capabilities to gather insights on system performance, usage patterns, and user satisfaction, such that continuous improvement is driven.

7. The data processing system of claim 1, further comprising an electronic filing integration module configured to streamline the submission of the generated structural engineering documents to relevant building departments.

8. The data processing system of claim 1, wherein the AI algorithm is configured to learn new structural engineering requirements and building codes based on the received user and engineer feedback.

9. The data processing system of claim 3, wherein the structural analysis further includes determining material properties of structural elements, comprising density, hardness, stiffness, tensile strength, compressive strength, and shear strength.

10. The data processing system of claim 1, wherein the machine learning model is periodically retrained using an updated dataset of engineered structures that incorporates the received user feedback and engineer feedback.

11. A method for generating structural engineering documents using a data processing system, the method comprising:
a. training, by the data processing system, a machine learning model using a dataset of engineered structures and instances of structural failures;
b. receiving input data for a target structure;
c. performing, by the data processing system, structural analysis on the target structure by:
i. simulating, using the trained machine learning model, structural behaviours of the target structure under various stresses and environmental conditions; and
ii. determining, based on the simulation, a combination of materials for structural elements of the target structure;
d. generating, by the data processing system, one or more structural engineering documents for the target structure based on the structural analysis;
e. integrating, by the data processing system, with one or more electronic filing systems; and
f. submitting, by the data processing system, the generated structural engineering documents to a relevant building department via the one or more electronic filing systems.

12. The method of claim 11, wherein the dataset of engineered structures comprises instances of structural failures, and wherein the machine learning model is trained to predict potential structural failures.

13. The method of claim 11, wherein simulating the structural behaviors of the target structure includes determining the structure's response to various loads, comprising wind, earthquake, snow, ocean waves, and temperature effects.

14. The method of claim 11, wherein determining the combination of materials for the structural elements involves selecting from materials comprising steel, concrete, timber, aluminum, plastic.

15. The method of claim 11, wherein simulating the structural behaviors includes analyzing the structure's response to various stresses, comprising compression, tension, shear, bending, and twisting.

16. The method of claim 11, wherein simulating the structural behaviors includes analyzing the structure's performance under various environmental conditions, comprising ambient temperature, corrosive environments, blast, and radiation.

17. The method of claim 11, further comprising refining the machine learning model based on user feedback, engineer feedback, and instances of structural failures.

18. The method of claim 11, further comprising providing analytical data analysis of the data processing system's capabilities to gather insights on system performance, usage patterns, and user satisfaction.

19. The method of claim 11, wherein the structural analysis further comprises finite element analysis (FEA) to model the structural behaviors of the target structure.

20. The method of claim 11, further comprising generating a 3D computer-aided design (CAD) model of the target structure based on the determined combination of materials, wherein the CAD model utilizes NURBS surfaces to represent the structural design.
